(19) United States
(12) Patent Application Publication
(10) Pub. No.: US 2017/0069472 A1
(43) Pub. Date: Mar. 9, 2017

(54) METHOD FOR CLEANING A PROCESS CHAMBER

(71) Applicants: IMEC VZW, Leuven (BE); TOKYO ELECTRON LIMITED, Tokyo (JP)

(72) Inventors: Shigeru TAHARA, Miyagi (JP); Dunja RADISIC, Leuven (BE)

(73) Assignees: IMEC VZW, Leuven (BE); TOKYO ELECTRON LIMITED, Tokyo (JP)

(21) Appl. No.: 15/120,396

(22) PCT Filed: Mar. 17, 2015
(86) PCT No.: PCT/EP2015/055499

§ 371 Date: Aug. 19, 2016

Related U.S. Application Data
(60) Provisional application No. 61/969,379, filed on Mar. 24, 2014.

(51) Int. Cl. H01J 37/32; B08B 9/08; B08B 7/00

(52) U.S. Cl. CPC H01J 37/32862; B08B 7/0035; B08B 9/08; H01J 37/32091; H01J 37/32715; H01J 2237/334

(57) ABSTRACT

The disclosure relates to a method of cleaning a process chamber of a capacitively coupled plasma reactor, the method comprising: a) Introducing a gas comprising 80-100% in volume of inert gas into the process chamber, wherein said inert gas is selected from the group consisting of neon, argon, krypton, xenon and combinations thereof; and b) Forming a plasma from said inert gas, thereby cleaning said process chamber.

### FIELD OF THE DISCLOSURE

The present disclosure relates to the field of plasma process chamber cleaning methods. More specifically it relates to a method of cleaning a process chamber of a capacitively coupled plasma reactor after dry etching.

### BACKGROUND OF THE DISCLOSURE

Plasma process chambers, and in particular those used for etching, often see their walls and/or electrode(s) covered by non-volatile deposits such as etching byproducts. This can lead to sample contamination when for instance some of these non-volatile deposits re-depose on a next sample. Also, process drift often occurs due to re-sputtering of those non-volatile deposits. It is therefore necessary for many applications that the plasma chamber remains free of such non-volatile material deposits. Making sure that the chamber is clean and keeping the chamber in this stable condition is therefore important. Most of the commonly used cleaning procedures are however not sufficient in removing the chamber contaminations, while very aggressive cleanings can damage hardware parts.

U.S. Pat. No. 8,211,238 discloses a copper etch process and a cleaning process that can be used to remove copper-containing species that have been deposited on the inner surfaces of a process chamber at substantially the same time that the copper etch process is being applied to a substrate. U.S. Pat. No. 8,211,238 discloses that, in an operation, the inner surfaces of the process chamber can be heated to a process temperature. It also discloses that, in another operation, a hydrogen input with a halogen based etch chemistry can react with the layer of etch byproducts (e.g. CuCl₂) that is formed on the inner surfaces of the process chamber. The non-volatile copper chloride is reduced to elemental copper and the chlorine combines with the hydrogen to form HCl that is volatile at the process temperature. It further discloses that in yet another operation, the elemental copper can react with the halogen based plasma to become one or more volatile species that can be removed from the process chamber through an outlet. However, this method is limited in its ability to clean deposits other than copper-containing species such as for instance non-volatile materials such as those typically formed upon dry etching of magnetic tunnel junction (MTJ) materials.

In view of the foregoing, there is a need in the art for a new plasma chamber cleaning method.

### SUMMARY OF THE DISCLOSURE

It is an object of embodiments of the present disclosure to provide a method for good process chamber cleaning in a capacitively coupled plasma reactor.

The present disclosure relates to a method of cleaning a process chamber of a capacitively coupled plasma reactor, the method comprising:

a) Introducing a gas comprising 80-100% in volume of inert gas into the process chamber, wherein said inert gas is selected from the group consisting of neon, argon, krypton, xenon and combinations thereof; and

b) Forming a plasma from said inert gas, thereby cleaning said process chamber.

The method of the present disclosure is particularly suited for cleaning a CCP reactor. It is much less suited for cleaning an ICP reactor. Without being bound by theory, this may be caused by the fact that an ICP reactor includes the need for a dielectric window. The potential difference between plasma bulk and the window's surface determines the efficiency of cleaning. To enhance this potential difference, ICP reactors permit applying the potential from outside of the window, at a so-called Faraday shield. However, even when a Faraday shield is present, the potential difference is consumed by dielectric window, making the potential difference between the plasma and the surface window not sufficient for cleaning. An additional or alternative explanation is that the plasma generated by an inert gas in an ICP reactor, is too distant from some of the inner surfaces (e.g. the electrodes) to enable their cleaning. CCP is peculiar in its ability to be cleaned by the claimed process.

It is an advantage of embodiments of the present disclosure that it may remove otherwise difficult to remove non-volatile materials, such as materials based on cobalt, platinum, nickel or iron.

It is an advantage of embodiments of the present disclosure that there is no need for heating, thereby reducing the cleaning time needed.

It is an advantage of embodiments of the present disclosure that the process is easy and can involve a relatively inexpensive and readily available gas such as Ar.

The above objective is accomplished by a method according to the present disclosure.

Particular and preferred aspects of the disclosure are set out in the accompanying independent and dependent claims. Features from the dependent claims may be combined with features of the independent claims and with features of other dependent claims as appropriate and not merely as explicitly set out in the claims.

These and other aspects of the disclosure will be apparent from and elucidated with reference to the embodiments described hereinafter.

As used herein, the terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the disclosure described herein are capable of operation in other sequences than described or illustrated herein.

Moreover, the terms top, under and the like in the description and the claims are used for descriptive purposes and not necessarily for describing relative positions. It is to be understood that the terms so used are interchangeable under appropriate circumstances and that the embodiments of the disclosure described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present disclosure, the only relevant components of the device are A and B.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the disclosure, various features of the disclosure are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed disclosure requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this disclosure.

Furthermore, while some embodiments described herein include some but not other features included in other embodiments, combinations of features of different embodiments are meant to be within the scope of the disclosure, and form different embodiments, as would be understood by those in the art. For example, in the following claims, any of the claimed embodiments can be used in any combination.

In the description provided herein, numerous specific details are set forth. However, it is understood that embodiments of the disclosure may be practiced without these specific details. In other instances, well-known methods, structures and techniques have not been shown in detail in order not to obscure an understanding of this description.

As used herein and unless provided otherwise, the term ‘capacitively coupled plasma’ (CCP) refers to a type of plasma resulting from the interaction of a gas with an electric field produced between two electrodes (typically separated by a small distance), thereby producing electrons within said gas. These electrons are then accelerated by a radio-frequency power supply, thereby producing a plasma. Another type of plasma is inductively coupled plasma (ICP), which refers to a type of plasma resulting from the interaction of a gas with electric currents produced by electromagnetic induction, that is, by time-varying magnetic fields. These currents are induced by a coil producing a magnetic field outside the reactor, with the magnetic field passing through a dielectric window into the reactor, and inducing a current therein.

An aspect of this disclosure provides a method for cleaning a process chamber of a capacitively coupled plasma reactor. The method includes introducing a gas comprising from 80% to 100% inert gas by volume into the process chamber. This inert gas can be any of neon, argon, krypton, xenon and combinations thereof. It also includes forming a plasma from said inert gas, thereby cleaning the process chamber.

In an embodiment the gas may comprise at least 90% of said inert gas by volume, more preferably at least 95%, even more preferably at least 98% and most preferably at least 99% of said inert gas by volume. The inert gas preferably comprises argon. In an embodiment, the inert gas may be argon.

The advantage of a higher percentage of the volume of the gas being an inert gas is an improved sputtering rate of the deposit, resulting in a more efficient cleaning. The advantage of using argon is that it offers the best balance of cleaning efficiency versus cost, as neon, krypton and xenon are much more expensive than argon, whilst neon is also surprisingly less effective.

In embodiments, the plasma may be formed under a pressure of up to 1 Torr. Such a high pressure is however not preferred.

Preferably, the plasma may be formed under a pressure of at most 50 mTorr, more preferably at most 30 mTorr, yet more preferably at most 20 mTorr.

In embodiments, the process chamber may comprise two parallel electrodes. In these embodiments, step b) may comprise applying an alternating voltage to at least one of the electrodes.

In embodiments, step b) may comprise applying a first alternating voltage to a first electrode and a second alternating voltage to a second electrode. The first and the second alternating voltages can have equal voltages or different voltages. The first and the second alternating voltages can have the same frequencies or different frequencies.

In embodiments, step b) may comprise applying an alternating voltage to a first electrode and a direct voltage to a second electrode.

In embodiments, one of the electrodes may be adapted for receiving a sample. As used herein and unless provided otherwise, the term “adapted for receiving” when relating to an electrode, covers any alternatives making the electrode suitable for receiving a sample. For instance, the mere fact that an electrode is a horizontal bottom electrode on which a sample can rest due to gravity makes already this electrode adapted for receiving a sample. A top electrode or a vertical electrode on the other hand, due to gravity, would need additional means for receiving (and in this case holding) the sample on that electrode. Such additional means can off course be present on a bottom electrode as well. In these embodiments where one of the electrodes is adapted for receiving a sample, an alternating voltage is preferably applied to the electrode adapted for receiving a sample.

In embodiments, one of the electrodes may be adapted for receiving a sample and the other electrode may not be adapted for receiving a sample. In a typical CCP reactor, the electrode adapted for receiving a sample is the bottom electrode and the electrode not adapted for receiving a sample is the top electrode. Hereinafter, the electrode adapted for receiving a sample will be referred to as the bottom electrode and the electrode not adapted for receiving a sample will be referred to as the top electrode.

In these embodiments wherein a top and a bottom electrode are present, it is preferred to apply an alternating voltage to the bottom electrode and an alternating or direct voltage to the top electrode. In these embodiments, applying a direct voltage to the top electrode is preferred as it leads to very good cleaning performance. If an alternating voltage is applied to the top electrode, this alternating voltage may alternate at a frequency of from 0.1 to 70 MHz, preferably 0.1-60 Mhz, more preferably 0.1-50 MHz, sill more preferably 0.1-40 MHz, yet more preferably 0.1-30 MHz, yet still more preferably 0.1-20 MHz and most preferably (if DC voltage is not used) 0.1-10 MHz. Lower frequencies for the top electrode tend to deliver better cleaning performances.

In any embodiments, it is preferred to apply an alternating voltage to the bottom electrode. This alternating voltage may alternate at a frequency of from 0.1 to 100 MHz. When a direct voltage is applied to the top electrode, the alternating voltage applied to the bottom electrode is preferably alternating at a frequency of from 2 to 70 MHz, preferably from 10 to 70 MHz, more preferably from 30 to 70 MHz, yet more preferably 40 to 70 MHz. Higher frequencies applied to the bottom electrode permits to generate a plasma at low pressure, which is preferred.

In embodiments, said process chamber may comprise two parallel electrodes and step b) of the method may comprise applying an alternating voltage at a frequency of from 2 MHz to 70 MHz to at least one of the electrodes. In embodiments, a direct (DC) voltage can be applied to the other electrode.

In embodiments, the process chamber may comprise two parallel electrodes and step b) of the method may comprise applying an electrical power of from 1000 W to 4000 W, preferably from 1500 W to 4000 W to at least one of the electrodes.

Preferably, this power (e.g. of from 1000 W to 4000 W) may be applied to the top electrode.

Higher powers are preferred because they permit a better and faster cleaning. Powers above 4000 W, while still useful for cleaning, could damage the chamber.

In embodiments, the gas (e.g. Ar) flowrate may be from 50 to 1500 sccm, e.g. from 100 to 1000 sccm.

In embodiments, step b) may last from 2 to 1000 s, depending on the configuration used and the desired degree of cleaning. Typically, step b) will last from 10 to 500 s.

In embodiments, the method may include introducing an oxygen reactant into the process chamber and forming a plasma from this oxygen reactant. These additional steps can be performed either before step a) or after step b). They are performed preferably before introducing the inert gas into the process chamber. This oxygen reactant step is especially advantageous for removing carbon based deposited materials. In embodiments, the process chamber may comprise at least one inner surface on which deposited materials containing carbon are present. In these embodiments, the oxygen reactant plasma may clean the inner surface from these materials

As used herein and unless provided otherwise, the term oxygen reactant refers to a gas molecule comprising at least one oxygen atom. Preferably, this gas molecule has from two to three atoms. Examples of oxygen reactants are O₂, O₃, CO2, H₂O and mixtures thereof. Preferably, the oxygen reactant comprises or is O₂.

When the oxygen reactant plasma is formed before introducing the inert gas, the oxygen reactant plasma is preferably evacuated from the chamber before the inert gas (from which a cleaning plasma will be formed) is introduced into the process chamber. Although carbon-based deposit materials can be removed without the use of an oxygen reactant plasma, forming an oxygen reactant plasma has the advantage to efficiently remove carbon deposits at a lower cost and with less chamber wear than by the use of the inert gas plasma alone. The combination oxygen reactant plasma step/inert gas plasma step has therefore the advantage to enable the removal of both carbon and low volatility (e.g. ferromagnetic metals) deposits at a lower cost and with less chamber wear than when the oxygen reactant plasma step is not used. The use of a mixture of oxygen reactant (e.g. more than 20 vol %) and inert gas (e.g. less than 80 vol %) to form a plasma is however detrimental to the performance of the cleaning. Both steps are therefore preferably separated.

In embodiments, the oxygen reactant plasma may be formed under a pressure of up to 1 Torr.

In embodiments, the process chamber may comprise two parallel electrodes and the step of generating an oxygen reactant plasma may comprise applying an electrical power of more than 500 W, preferably more than 2000 W to at least one of the electrodes.

Preferably, this power (e.g. of from 800 W to 3000 W) may be applied to the top electrode.

In embodiments, the oxygen reactant flow rate may be from 100 to 2000 sccm. In embodiments, the oxygen reactant plasma step may last from 1 to 500 s, depending on the configuration used and the desired degree of cleaning. Typically, the oxygen reactant plasma step (when present) will last from 5 to 200 s.

In embodiments, the process chamber may comprise at least one inner surface on which deposited materials to be cleaned are present. For instance, the method may be performed subsequent to an etching process (or step) in which a material is etched in the process chamber, thereby producing the deposited materials. In embodiments, the etching process may for instance be performed via reactive ion etching wherein the etching operates via sputtering with high energy ions. In embodiments, the etched material may be a non-volatile material. The non-volatile material may comprise a metal element selected from the group consisting of cobalt, platinum, nickel, iron, palladium, manganese, chromium and magnesium. In embodiments, the deposited material may comprise a metal element selected from the group consisting of cobalt, platinum, nickel, iron palladium, manganese, chromium, magnesium. Such materials are particularly difficult to clean with conventional methods but are readily cleaned with methods according to embodiments of the present disclosure. In embodiments, the etched material may be a ferromagnetic material (e.g. comprising a metal element selected from the group consisting of cobalt, platinum, nickel and iron). Although platinum is not as such ferromagnetic, platinum alloys (e.g. Pt₃Fe or PtCo) can be ferromagnetic and therefore ferromagnetic materials may comprise the metal element platinum. In embodiments, the deposited material may comprise a metal element selected from the group consisting of cobalt, platinium, nickel and iron.

Ferromagnetic materials are for instance used as magnetic tunnel junction (MTJ) materials. Dry etching of magnetic tunnel junction (MTJ) materials is one of the most challenging steps in building working memory devices that use MTJ materials. The main reason is that etching of the common MTJ films (comprising elements such as Co, Pt, Ni, and Fe) leads to the deposition of non-volatile products on the sidewalls of the process chamber. These non-volatile products do not easily form volatile products with commonly used dry etching gases or chamber cleaning gases. This leads to several problems:

Firstly, electrical shorting is very commonly detected after the processing as a result of re-deposition of etched sidewall metallic layers on the MTJ elements.

Secondly, the etched materials get easily re-sputtered on the interior of the dry etch chamber causing process drifts, if the chamber cleaning is not efficient.

Embodiments of the present disclosure are particularly suited for use after dry etching of MTJ materials and especially after dry etching of MTJ materials.

In embodiments, said cleaning may comprise removing the deposited materials from the inner surface.

In embodiments, the process chamber may comprise two parallel electrodes, wherein one of the electrodes is adapted for receiving a sample and the other electrode has deposited materials thereon and wherein the cleaning comprises removing the deposited materials from this other electrode.

In embodiments, the method may further comprise the step of introducing a removable protective substrate into the process chamber in such a manner that step b) is performed in presence of this substrate. In embodiments, the protective substrate may be introduced before step a). In embodiments, the plasma of an inert gas may be formed in the process chamber in the presence of this substrate and preferably also the inert gas may be introduced into the process chamber in the presence of this substrate. The removable protective substrate preferably covers at least part of an inner surface of the process chamber. Preferably, the protective substrate covers at least part of the electrode adapted for receiving a sample. An advantage of the use of a removable protective substrate is to prevent contamination of the inner surface during the cleaning process. The advantage of covering the bottom electrode is to prevent contamination of this electrode by the cleaning process. The removable protective substrate is typically a dummy wafer.

In embodiments, if a sample is present in the process chamber to be cleaned, the method may further comprise, before step a), an optional step of removing said sample form said chamber and optionally replacing said sample with a removable protective substrate such as a dummy wafer.

In embodiments, the plasma formed in step b) may remove deposited materials by sputtering the deposited materials. In embodiments, step b) may be maintained until an end-point in optical emission spectroscopy for the deposited material to be removed is reached.

In embodiments, the method may further comprise a step, after step b), of evacuating the sputtered materials. This can for instance be performed by flushing the sputtered material toward an outlet of the process chamber.

### BRIEF DESCRIPTION OF THE DRAWINGS

FIG. 1 is a flowchart of the method operations for cleaning a process chamber, in accordance with an embodiment of the present disclosure.

FIG. 2 is a schematic view of a capacitively coupled plasma reactor as used in embodiments of the present disclosure.

FIG. 3 is a schematic view of another capacitively coupled plasma reactor, as used in embodiments of the present disclosure.

FIG. 4 is a schematic view of a process chamber for a capacitively coupled plasma reactor, as used in embodiments of the present disclosure.

The drawings are only schematic and are non-limiting. In the drawings, the size of some of the elements may be exaggerated and not drawn on scale for illustrative purposes. Any reference signs in the claims shall not be construed as limiting the scope. In the different drawings, the same reference signs refer to the same or analogous elements.

### DETAILED DESCRIPTION OF ILLUSTRATIVE EMBODIMENTS

The present disclosure will be described with respect to particular embodiments and with reference to certain drawings but the disclosure is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the disclosure.

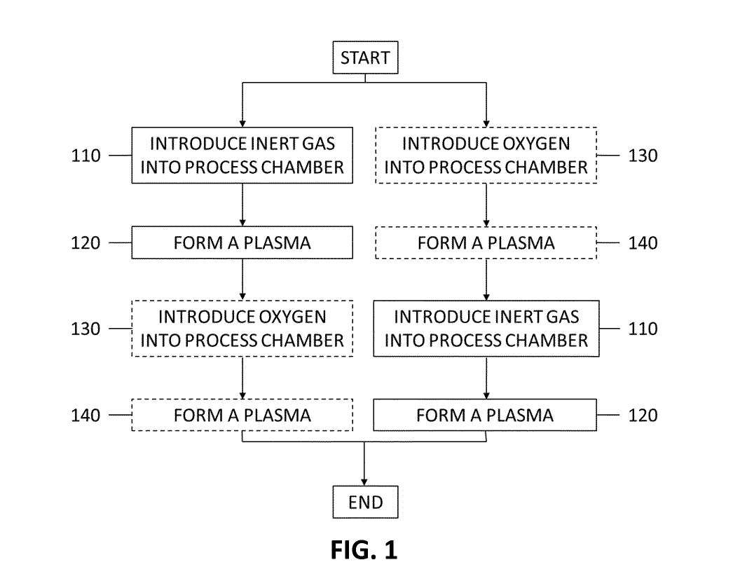

FIG. 1 is a flowchart of the method operations for cleaning a process chamber of a capacitively coupled plasma reactor in accordance with an embodiment of the present disclosure. In an operation 110 “introduce inert gas into process chamber” a gas comprising 80-100% in volume of inert gas is introduced into the process chamber, wherein said inert gas is selected from the group consisting of neon, argon, krypton, xenon and combinations thereof.

In an operation 120 “form a plasma” a plasma is formed from said inert gas, thereby cleaning said process chamber. In an operation 130 “introduce oxygen into process chamber” oxygen reactant (e.g. oxygen) is introduced into the process chamber. In an operation 140 “form a plasma” a plasma is formed from said oxygen reactant, thereby cleaning said process chamber of carbon based deposited materials. Operation 130 with subsequent operation 140 are optional steps, indicated by the textboxes having dashed outlines. The left branch of FIG. 1 depicts an embodiment where an oxygen reactant plasma is generated after the generation of an inert gas plasma. The right branch of FIG. 1 depicts a preferred embodiment where an oxygen reactant plasma is generated before the generation of an inert gas plasma.

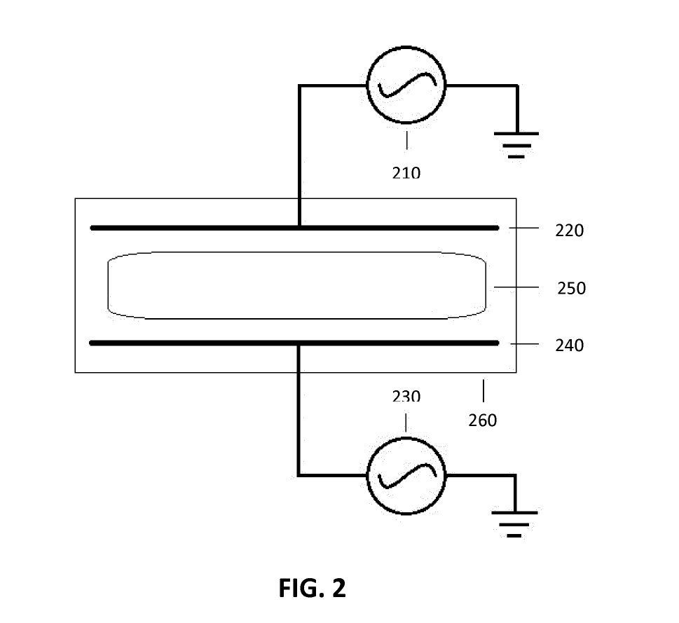

FIG. 2 is a schematic view of a capacitively coupled plasma reactor undergoing cleaning in embodiments of the present disclosure. An AC power supply 210 provides a power with a frequency of from 0.1 to 70 MHz to the top electrode 220. For the inert gas this power may be in the range of from 1000 W to 4000 W, preferably in the range of from 1500 W to 4000 W (e.g. 1500 W). A higher power value is considered advantageous, as it increases the sputtering rate, and therefore reduces cleaning time. Simultaneously the AC power supply 230 may provide a power with a frequency of from 0.1 to 100 MHz (e.g. 400 kHz) to the bottom electrode 240. This power may be up to 200 W for the inert gas. 210 and 230 together provide power for forming a plasma 250 in the process chamber 260 once a suitable gas is introduced. Preferably, at least one of the top 210 or of the bottom 230 power supply provides a power of at least 2 MHz. 210 and 220 together provide the power for forming a plasma 250 in the process chamber once a suitable gas is introduced.

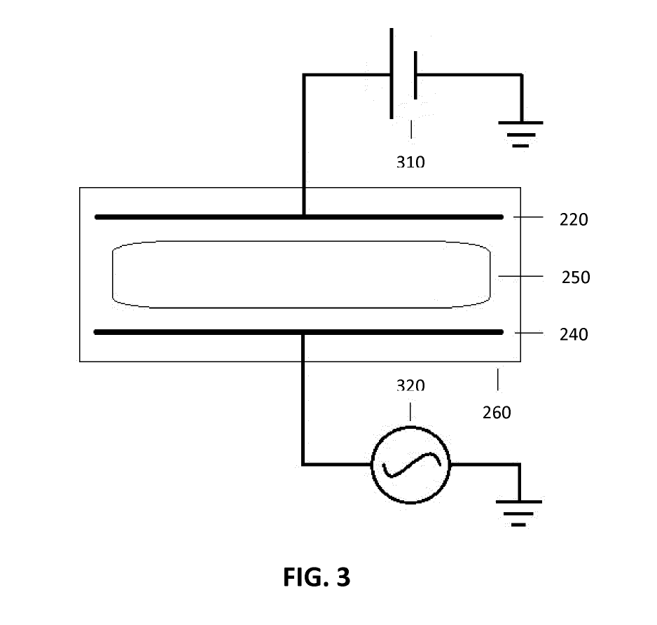

FIG. 3 is a schematic view of a capacitively coupled plasma reactor undergoing cleaning in embodiments of the present disclosure. The reactor comprises two electrodes 220, 240 in a process chamber 260. A DC power supply 310 provides a power to the top electrode 220. For the inert gas this power may be in the range of from 1000 W to 4000 W, preferably in the range of from 1500 W to 4000 W. A higher power value is considered advantageous, as it increases the sputtering rate, and therefore reduces cleaning time. Simultaneously the AC power supply 320 may provide a power with a frequency of from 2 MHz to 70 MHz (e.g. 40 MHz) to the bottom electrode 240. This power may be up to 200 W for the inert gas. 310 and 320 together provide the power for forming a plasma 250 in the process chamber once a suitable gas is introduced.

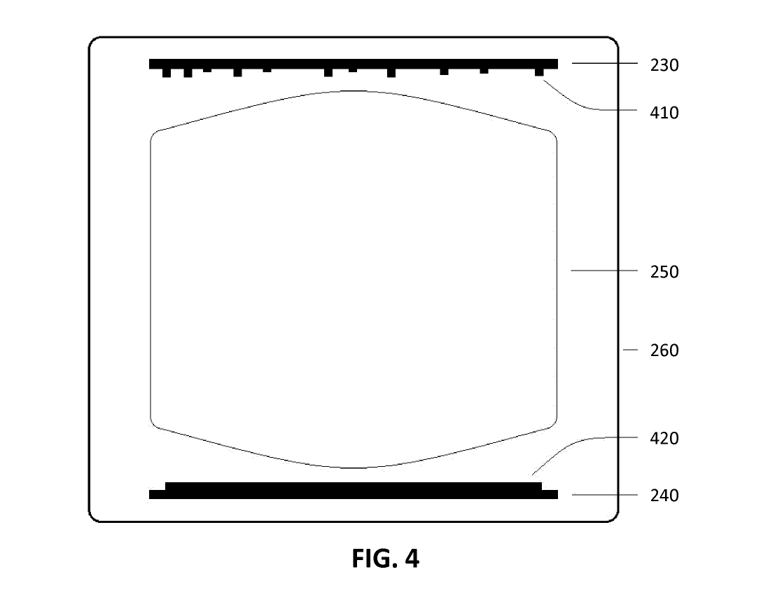

FIG. 4 is a schematic overview of a process chamber, as used in accordance with an embodiment of the present disclosure. In this embodiment there are deposited materials 410 on the surface of the top electrode 230. On the bottom electrode 240 a removable protective substrate 420 is placed. This protects the bottom electrode 240 during the cleaning procedure, and also prevents the removed deposited materials from depositing on the surface of 240, as these materials would pollute the bottom electrode 240.

An illustrative example of a method according to an embodiment of the present disclosure is the cleaning of a deposit after etching of a cobalt platinum (CoPt) substrate. For etching this substrate, a mixture of CH₄, CO and argon was used. This lead to the deposition of a cobalt platinum material 410 as well as a carbon based material on the electrode 230 opposite the electrode 240 supporting the etched substrate. The electrode on which the deposited material is present will henceforth be referred to as the ‘top electrode’. For cleaning these deposited materials 410, different methods were attempted. Trial 1-1 (comparative) comprised the steps of first cleaning with a plasma generated from CH₄ and CO, and then a second step consisting of cleaning with an oxygen reactant plasma. This did not result in removal of the CoPt deposit from the top electrode. Trial 1-2 (comparative) added a further step after the oxygen reactant plasma consisting of 5 cycles of a CF₄ plasma. This did not result in any noticeable improvement over the previous trial.

Per the method of the present disclosure, trial 2-1 comprised cleaning by sputtering with an oxygen reactant plasma, followed by sputtering with an argon plasma. The oxygen reactant plasma treatment was operated for 45 s with an O₂ flow of 600 sccm, under a pressure of 30 mTorr. An alternating current at a frequency of 60 MHz and a power of 1000 W was applied to the top electrode 230. An alternating current at a frequency of 400 kHz and a power of 500 W was applied to the bottom electrode. The Ar plasma treatment was operated for 120 s with a pure Ar flow of 300 sccm, under a pressure of 10 mTorr. An alternating current at a frequency of 60 MHz and a power of 1500 W was applied to the top electrode. An alternating current at a frequency of 400 kHz and a power of 200 W was applied to the bottom electrode. This resulted in a clean surface for the top electrode. This was further verified by the observation of a substantial reduction of the corresponding signal in optical emission spectroscopy (OES) for both cobalt and platinum. This was measured for cobalt at 241, 304, 341 and 346 nm, and for platinum at 265, 270, 274 and 283 nm. For trial 2-2, the step of cleaning with an O₂ plasma is omitted and the Ar plasma treatment is slightly extended in time. A clean top electrode is also obtained.

1. A method of cleaning a process chamber of a capacitively coupled plasma reactor, the method comprising:
a) Introducing a gas comprising 80-100% in volume of inert gas into the process chamber, wherein said inert gas is selected from the group consisting of neon, argon, krypton, xenon and combinations thereof; and
b) Forming a plasma from said inert gas, thereby cleaning said process chamber.

2. The method according to claim 1, wherein the gas comprises at least 90% of said inert gas, preferably at least 99% of said inert gas.

3. The method according to claim 1, wherein the inert gas is argon.

4. The method according to claim 1, wherein the plasma is formed under a pressure of at most 50 mTorr.

5. The method according to claim 1, further comprising the steps of:
c) Introducing an oxygen reactant into the process chamber; and
d) Forming a plasma from the oxygen reactant, wherein said steps c) and d) are performed either before step a) or after step b).

6. The method according to claim 5, wherein step c) and d) are performed before step a).

7. The method according to claim 5, wherein said process chamber comprises at least one inner surface on which deposited materials containing carbon are present and wherein said oxygen reactant plasma cleans the inner surface from these materials.

8. The method according to claim 1, wherein said process chamber comprises two parallel electrodes and wherein step b) comprises applying an electrical power of from 1000 W to 4000 W to at least one of said electrodes.

9. The method according to claim 1, wherein said process chamber comprises two parallel electrodes and wherein step b) comprises applying an alternating voltage at a frequency of from 2 to 100 MHz to at least one of said electrodes.

10. The method according to claim 9, wherein step b) comprises applying an alternating voltage at a frequency of from 2 to 70 MHz to one electrode and a DC voltage to the other electrode.

11. The method according to claim 1, wherein said process chamber comprises at least one inner surface on which deposited materials to be cleaned are present, wherein said deposited materials comprise at least a compound comprising a metal element selected from the group consisting of cobalt, platinum, nickel, iron, chromium, magnesium, palladium, and manganese, and wherein said cleaning comprises removing the deposited materials from said inner surface.

12. The method according to claim 1, wherein step a) and b) are performed subsequent to an etching process in which a material is etched, said material comprising at least a metal element selected from the group consisting of cobalt, platinum, nickel, iron, chromium, magnesium, palladium, and manganese.

13. The method according to claim 12, wherein said etched material is a ferromagnetic material comprising at least a metal element selected from the group consisting of cobalt, platinum, nickel, and iron.

14. The method according to claim 1, wherein said process chamber comprises two parallel electrodes, wherein one of the electrodes is adapted for receiving a sample and the other electrode has deposited materials thereon and wherein said cleaning comprises removing the deposited materials from said other electrode.

15. The method according to claim 1, further comprising the step of introducing a removable protective substrate in the process chamber in such a manner that step b) is performed in presence of said substrate.
